(19) United States
(12) Patent Application Publication
(10) Pub. No.: US 2026/0339309 A1
(43) Pub. Date: Oct. 29, 2026

(54) Error Factor Analysis Device and Error Factor Analysis Method

(71) Applicant: Hitachi High-Tech Corporation, Minato-ku, Tokyo (JP)

(72) Inventors: Yasuhiro YOSHIDA, Tokyo (JP); Masayoshi ISHIKAWA, Tokyo (JP); Fumihiro SASAJIMA, Tokyo (JP); Shigeo OHKOSHI, Tokyo (JP)

(21) Appl. No.: 19/123,440

(22) PCT Filed: Nov. 16, 2022
(86) PCT No.: PCT/JP2022/042563

§ 371 Date: Apr. 23, 2025

(51) Int. Cl. G05B 23/02

(52) U.S. Cl. CPC G05B 23/024; G05B 23/0281

(57) ABSTRACT

An error factor analysis device estimates a small process constituting an inspection process based on a data set measured by an inspection device. The error factor analysis device includes: an error label assignment unit configured to estimate an error-related evaluation point related to an evaluation point where an error is detected from evaluation points of small processes other than a small process including an evaluation point where an error is detected, and assign an error label to the evaluation point where the error is detected and the error-related evaluation point; an error correlation calculation unit configured to estimate, based on a difference in data between an evaluation point to which the error label is assigned and an evaluation point to which the error label is not assigned, a feature having a large correlation with error occurrence for each small process; an abnormality degree calculation unit configured to calculate a feature-based abnormality degree for each small process according to a degree of statistical data deviation between the evaluation point to which the error label is assigned and the evaluation point to which the error label is not assigned for the feature having the large correlation; and an abnormal process estimation unit configured to estimate a small process of an error cause based on an abnormality degree for each small process.

### TECHNICAL FIELD

The present invention relates to an error factor analysis device and an error factor analysis method for analyzing a factor of an error occurring in an inspection device or the like.

### BACKGROUND ART

A semiconductor inspection device and a semiconductor measurement device perform inspection for each inspection point on a surface of a semiconductor wafer or perform measurement for each evaluation point according to a setting parameter called a recipe. However, when an insufficiently adjusted recipe is used or when characteristics of the device are changed due to a change over time, there is a possibility that an error occurs in inspection or measurement, which is a cause of a decrease in an operation rate of the device. When analyzing a factor of this type of error, a user of the device often needs to perform a manual work such as checking each inspection value, each measurement value, or a captured image (hereinafter, referred to as an SEM image) of a scanning electron microscope, and it takes a considerable time to analyze the error factor.

One of the problems in error factor analysis is that it is necessary to accurately estimate a cause process of an error. An inspection process and a measurement process of a semiconductor can be further divided into a plurality of small processes such as alignment, addressing, and length measurement, and in each small process, a matching score between a template image registered in advance in a recipe and an SEM image obtained by imaging an evaluation point is calculated, and when the matching score is equal to or larger than a threshold, it is determined that pattern detection is successful, and the processing proceeds to the next small process.

However, if the setting of the threshold is inappropriate, even though it is a small process in which it is determined that the pattern detection has failed, it may slip the error determination and shift to the next small process, and it may be erroneously estimated that there is an error cause in a subsequent small process in which there is actually no error. Therefore, in order to accurately analyze an error factor, it is important to accurately estimate a small process in which an error has occurred.

Here, a substrate inspection system of PTL 1 is known as a technique in the related art for estimating a small process in which an error or a failure has occurred. For example, the abstract of the document describes that “even an unskilled person can easily recognize a cause of a defect”. The paragraph 0056 describes that “an analysis program database 221, an analysis program selection table 222, a cause and measure table 223, a cause and basis table 224, a display image database 225, or the like are provided in an analysis information storage unit 202”. FIG. 12 to FIG. 14 of the document illustrate a configuration of each table, and FIG. 15 discloses defect cause identification processing using each table.

As described above, PTL 1 discloses a technique in which a table of a feature of a measurement value of each process and a cause process is configured in advance, and the cause process is estimated by referring to the table.

### CITATION LIST

### Patent Literature

PTL 1: JP2006-339445A

### SUMMARY OF INVENTION

### Technical Problem

Here, when an inspection and measurement recipe used in a semiconductor inspection device or a semiconductor measurement device is changed, a mechanism of error occurrence also changes, and therefore, in order to use the defect cause identification processing of PTL 1, it is necessary to configure various tables for each recipe. Since the same recipe can be used for a long period of time in a production process for manufacturing small variety and large-lot semiconductor products, even when various tables are configured every time the recipe is switched, the labor is not so large. However, since it is necessary to frequently switch the recipe in a production process for manufacturing small-lot and large variety semiconductor products, it is not realistic to configure various tables every time the recipe is switched.

As another method, a method for estimating a cause process by applying an abnormality detection method and determining the presence or absence of an abnormality in each process based on a deviation degree from normal data collected in advance is conceivable. However, in this case, since a work is necessary to define the normal data for each of several tens or several hundreds of recipes that are frequently switched, knowledge and man-hours for distinguishing the normal data are required, which is difficult.

Therefore, an object of the invention is to provide a technique capable of estimating an error factor by estimating a cause process of a detected error and analyzing data of the error cause process without configuring a relationship table between a measurement value and the error cause process or collecting and defining normal data.

### Solution to Problem

In order to solve the above problem, an error factor analysis device according to the invention estimates, when a data set measured by an inspection device includes an error, a small process of an error cause from a plurality of o small processes constituting an inspection process based on the data set. The error factor analysis device includes: an error label assignment unit configured to estimate an error-related evaluation point related to an evaluation point where an error is detected from evaluation points of small processes other than a small process including an evaluation point where an error is detected, and assign an error label to the evaluation point where the error is detected and the error-related evaluation point; an error correlation calculation unit configured to estimate, based on a difference in data between an evaluation point to which the error label is assigned and an evaluation point to which the error label is not assigned, a feature having a large correlation with error occurrence for each small process; an abnormality degree calculation unit configured to calculate a feature-based abnormality degree for each small process according to a degree of statistical data deviation between the evaluation point to which the error label is assigned and the evaluation point to which the error label is not assigned for the feature having the large correlation; and an abnormal process estimation unit configured to estimate a small process of an error cause based on an abnormality degree for each small process.

### Advantageous Effects of Invention

According to an error factor analysis device and an error factor analysis method of the invention, even when a recipe of a product or a measurement and inspection device is changed, it is possible to estimate a cause process of a detected error without configuring various tables for each recipe or collecting and defining normal data.

Problems, configurations, and effects other than those described above will be clarified by the following description of embodiments.

### BRIEF DESCRIPTION OF DRAWINGS

FIG. 1 is a schematic diagram illustrating a configuration example of an information processing system according to Embodiment 1.

FIG. 2 is an example of an inspection process of a semiconductor inspection device.

FIG. 3 is a functional block diagram of an error factor analysis device according to Embodiment 1.

FIG. 4 is a processing flowchart of the error factor analysis device according to Embodiment 1.

FIG. 5 is an example of process-classified data to which an error label is assigned.

FIG. 6 is an example of an analysis result displayed on a terminal.

FIG. 7 is a functional block diagram of an error factor analysis device according to Embodiment 2.

FIG. 8 is a schematic diagram illustrating a calculation method of a total abnormality degree according to Embodiment 2.

FIG. 9 is a functional block diagram of an error factor analysis device according to Embodiment 3.

FIG. 10 is a schematic diagram illustrating a calculation method of an error factor estimation result according to Embodiment 3.

### DESCRIPTION OF EMBODIMENTS

Hereinafter, embodiments of an error factor analysis device and an error factor analysis method of the invention will be described with reference to the drawings. In the following, a “semiconductor inspection device” includes not only a device for measuring a dimension of a pattern formed on a surface of a semiconductor wafer, but also a device for inspecting the presence or absence of a defect in the pattern formed on the surface of the semiconductor wafer, a device for inspecting the presence or absence of a defect in a bare wafer on which no pattern is formed, and a composite device combining these devices. In addition, an “inspection” is also used in the meaning of measurement, and an “inspection operation” is also used in the meaning of measurement operation. Further, an “inspection target” refers to not only a wafer as a measurement target or an inspection target but also a measurement target region or an inspection target region in the wafer. the following description, an “error” includes not only a measurement failure or a device failure but also a sign of an error such as an alert or a warning message.

### Embodiment 1

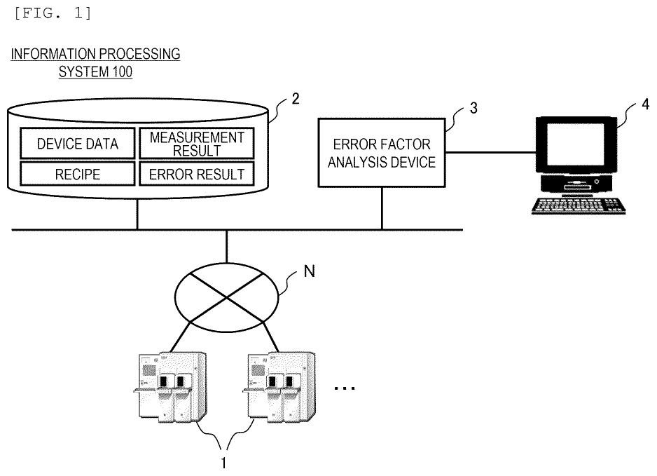

First, an error factor analysis device according to Embodiment 1 of the invention will be described with reference to FIGS. 1 to 7.

### (Outline of Information Processing System)

FIG. 1 is a schematic diagram illustrating a configuration example of an information processing system 100 according to the embodiment. As illustrated in the drawing, the information processing system 100 includes a semiconductor inspection device 1, a database 2, an error factor analysis device 3, a terminal 4, and a network N. Hereinafter, each will be sequentially described.

The semiconductor inspection device 1 is a device or the like for inspecting a dimension of a pattern formed on a surface of a semiconductor wafer, and is connected to the database 2 and the error factor analysis device 3 via the network N.

The database 2 is a recording device that records data such as device data, recipes, measurement results, and error results sent from the semiconductor inspection device 1.

The error factor analysis device 3 is a device for analyzing an error factor when there is an error in an inspection process performed by the semiconductor inspection device 1, and is specifically a computer including hardware such as an arithmetic device such as a CPU, a storage device such as a semiconductor memory, and a communication device. The error factor analysis device 3 may be an on-premise device operated in a facility managed by a user of the semiconductor inspection device 1, or may be a cloud operated outside the facility. A function of the factor analysis device 3 may be incorporated in the semiconductor inspection device 1.

The terminal 4 is a device including a display that functions as a graphical user interface (GUI) when an analysis result of the error factor analysis device 3 is presented to the user, and is communicably connected to the error factor analysis device 3 via a wired or wireless communication line.

### (Data Recorded in Database 2)

Data transmitted from the semiconductor inspection device 1, recorded in the database 2, and analyzed by the error factor analysis device 3 includes, for example, device data, a recipe, a measurement result, and an error result. Hereinafter, each piece of data will be sequentially described.

The device data includes a device-specific parameter, device-machine difference correction data, and an observation condition parameter. The device-specific parameter is a correction parameter used to operate the semiconductor inspection device 1 according to a prescribed specification. The device-machine difference correction data is a parameter used to correct a machine difference between semiconductor inspection devices. The observation condition parameter is, for example, a parameter that defines an observation condition of a scanning electron microscope (SEM) such as an acceleration voltage of an electron optical system.

The recipe includes a wafer map, various parameters (alignment parameter, addressing parameter, and length measurement parameter), a template image, or the like. The wafer map is a coordinate map (for example, coordinates of a pattern) of the surface of the semiconductor wafer. The alignment parameter is, for example, a parameter used to correct a deviation between a coordinate system of the surface of the semiconductor wafer and a coordinate system inside the semiconductor inspection device 1. The addressing parameter is, for example, information for specifying a characteristic pattern present in the inspection target region among patterns formed on the surface of the semiconductor wafer. The length measurement parameter is a parameter describing a condition for measuring a length, and is, for example, a parameter for designating a part of the pattern to be measured. The template image is a reference image for detecting an evaluation point by pattern matching.

The recipe may include the number of evaluation points, coordinate information of an evaluation point (EP), an imaging condition when an image is captured, or the like. In addition, the recipe may include an evaluation point, coordinates of an image acquired in a preparation stage for measuring the evaluation point, an imaging condition, or the like.

The measurement result includes a length measurement result, image data, and an operation log. The length measurement result describes a result of measuring a length of the pattern on the surface of the semiconductor wafer. The image data is an observation image of the semiconductor wafer. The operation log is data describing an internal state of the semiconductor inspection device 1 in each operation process of alignment, addressing, and length measurement. Examples thereof include an operating voltage of each component and coordinates of an observation field of view.

When an error has occurred, the error result is a parameter indicating an operation process among the alignment, the addressing, and the length measurement in which the error has occurred.

### (Outline of Inspection Process)

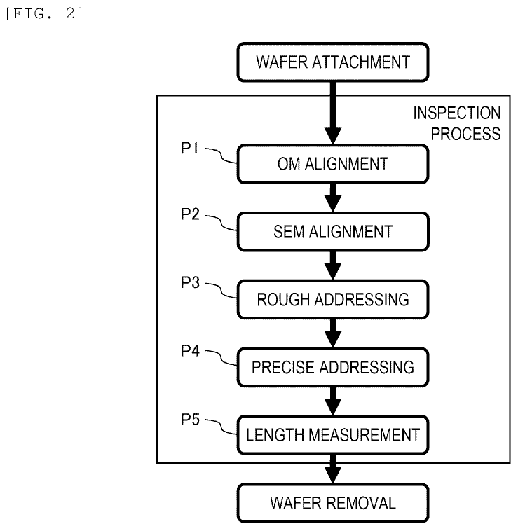

FIG. 2 illustrates an example of the inspection process of the semiconductor inspection device 1. The inspection process illustrated here is disassemble into five operation processes (small processes) from a process P1 to a process P5. That is, in the process P1, a positional deviation between a measurement wafer and a stage of the semiconductor inspection device is corrected by alignment in an optical (OM) mode. Next, in the process P2, the positional deviation between the measurement wafer and the stage is corrected by alignment in an electron beam (SEM) mode. Thereafter, in the processes P3 and P4, a field of view is moved to length measurement coordinates by addressing. Finally, in the process P5, the dimension of the pattern formed on the surface of the measurement wafer is measured. Through the above inspection process, the semiconductor inspection device 1 inspects the semiconductor wafer.

Here, in each operation process, a matching score between the template image registered in the recipe and the SEM image obtained by imaging the evaluation point is calculated, and when the matching score is equal to or larger than a threshold, it is determined that the pattern detection is successful, and the inspection process proceeds to the next operation process. However, if the threshold is inappropriate, even though the pattern detection fails, for example, a position different from the original position is detected, the inspection process may slip error determination and proceed to the next operation process. In this case, there is an error cause in an operation process in which slipping has occurred, which is different from an operation process in which an error has actually been detected.

Therefore, in the embodiment, the error factor analysis device 3 as described below is provided such that even when an error is detected in a subsequent operation process, a previous operation process as the error cause is estimated, and an error factor can be accurately analyzed based on data acquired in the previous operation process.

### (Configuration and Processing Content of Error Factor Analysis Device)

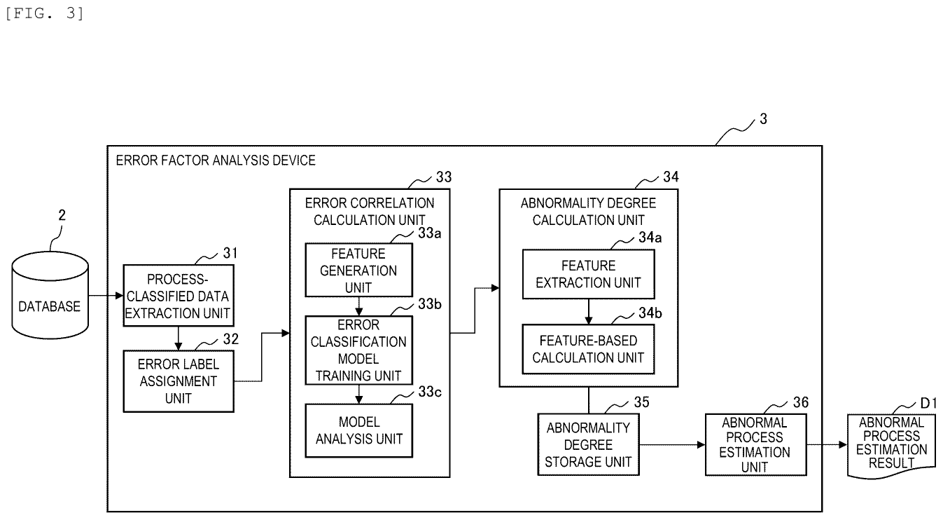

FIG. 3 illustrates a detailed configuration of the error factor analysis device 3 according to the Embodiment. As illustrated here, the error factor analysis device 3 includes a process-classified data extraction unit 31, an error label assignment unit 32, an error correlation calculation unit 33, an abnormality degree calculation unit 34, an abnormality degree storage unit 35, and an abnormal process estimation unit 36, and outputs an abnormal process estimation result D1 using these units. The error correlation calculation unit 33 includes a feature generation unit 33a, an error classification model training unit 33b, and a model analysis unit 33c. The abnormality degree calculation unit 34 includes a feature extraction unit 34a and a feature-based calculation unit 34b. Each functional unit is implemented by the arithmetic device of the error factor analysis device 3, which is a general computer, executing a predetermined program read into the storage device.

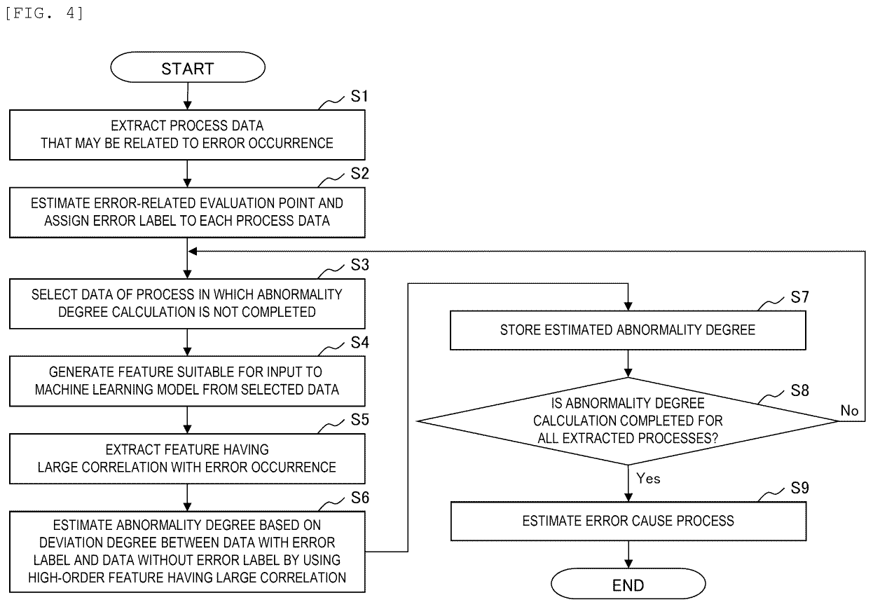

FIG. 4 is a processing flowchart of the error factor analysis device 3. Hereinafter, error factor analysis processing by the error factor analysis device 3 will be described in detail with reference to FIGS. 3 and 4 as appropriate.

### ((Step S1))

First, in step S1, the process-classified data extraction unit 31 acquires, from the database 2, a data set measured by the semiconductor inspection device 1 using a recipe for which an error factor is to be analyzed, and divides data for each operation process. In general, since the data set collected in the database 2 is given an identification number for distinguishing in which operation process the data set is measured, the data set can be divided into measurement data for each operation process using the identification number.

Then, measurement data of operation process that may be related to the detected error is extracted from the divided measurement data. The operation process that may be related to the error can be data of, for example, an operation process in which the error is detected and an operation process upstream thereof, a series of operation processes of a repetitive operation of addressing and length measurement, an operation process close to a measurement timing, or the like.

### ((Step S2))

Next, in step S2, for process data extracted in step S1, the error label assignment unit 32 assigns an error label to an evaluation point where an error is detected, and also assigns an error label to a related evaluation point (error-related evaluation point) estimated to affect an inspection performance of the evaluation point.

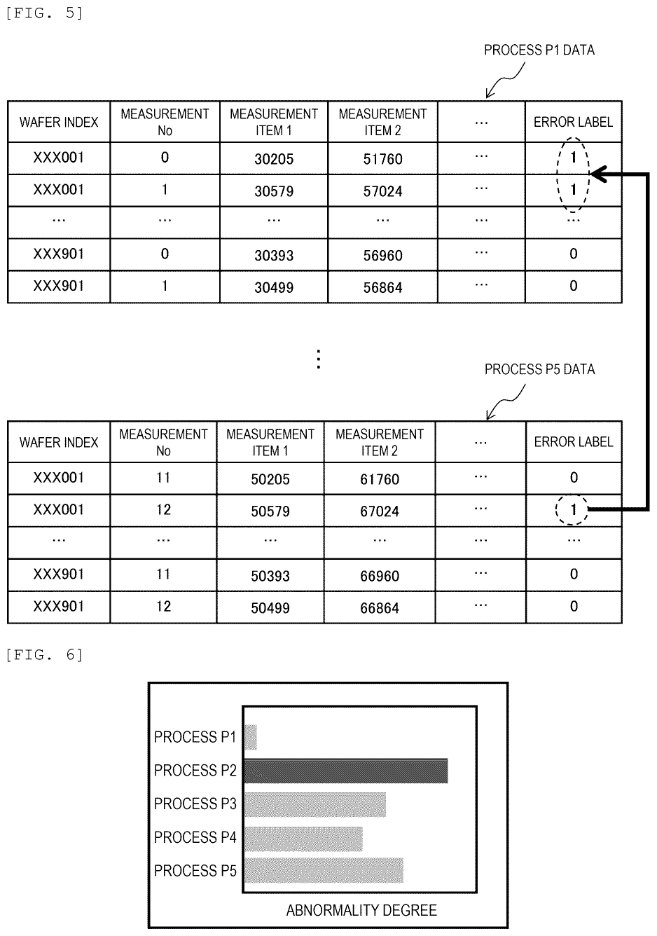

FIG. 5 illustrates an example of process-classified data to which an error label is assigned in this manner. FIG. 5 is a diagram in which process P1 data and process P5 data constituting the data set measured by the semiconductor inspection device 1 are extracted and displayed. In each piece of process-classified data, “wafer INDEX” in the first column from the left is an identification number for distinguishing semiconductor wafers. The “measurement No” in the second column from the left is a serial number indicating a number of the evaluation point on the same semiconductor wafer. In an estimation method of the error-related evaluation point in this step, for example, when an error is detected in a measurement item in which the “measurement No” of the semiconductor wafer whose “wafer INDEX” is “XXX001” in the process P5 data is “12”, an evaluation point in which the “wafer INDEX” is the same as the semiconductor wafer and the “measurement No” is smaller (for example, the evaluation point in which the “wafer INDEX” is “XXX001” and the “measurement No” is “0” or “1” in the process P1 data) is estimated as the error-related evaluation point. Thereafter, the error label assignment unit 32 assigns an error label “1” to the error-related evaluation point estimated in this manner and an error detection evaluation point serving as a starting point thereof, as illustrated in the drawing.

### ((Step S3))

In step S3, the error correlation calculation unit 33 selects, from the process-classified data extracted in step S1, one (the process P1 data or the process P5 data in the example of FIG. 5) in which the abnormality degree calculation has not been completed as a target of processing in step S4 and subsequent steps.

### ((Step S4))

In step S4, the error correlation calculation unit 33 generates a feature suitable for an input to a machine learning model based on the data (for example, the process P1 data in FIG. 5) selected in step S3. Therefore, specifically, the following processing is executed.

First, the feature generation unit 33a calculates a correlation degree of each feature with the error occurrence based on a difference in data between the evaluation point with the error label assigned in step S2 and the evaluation point without the error label. Next, the feature generation unit 33a generates, by using the process-classified data to be processed, a feature suitable for an input of a machine learning model that distinguishes between data with an error label and data without an error label. Here, for example, scaling or statistical processing of measurement data, encoding of a categorical variable, creation of a complex feature obtained by combining a plurality of pieces of data such as an interaction feature, or the like can be used to generate the feature.

Next, the error classification model training unit 33b uses the feature generated by the feature generation unit 33a or the error label assigned in step S2 as an input, and trains an error classification model for classifying the input based on a difference in tendency between the data of the evaluation point with the error label and the data of the evaluation point without the error label. The error classification model may be generated using any machine learning algorithm such as an algorithm based on a decision tree such as Random Forest or XGBoost, or a neural network.

Further, the model analysis unit 33c calculates the correlation degree indicating how much each input feature has affected an error prediction result as a model output, for the error classification model trained by the error classification model training unit 33b. For example, when an error detection model is configured by an algorithm based on a decision tree, the correlation degree can be evaluated by a feature importance calculated based on the number of features appearing in a branch in the model, an improvement value of an objective function, or the like, or a shapley additive explanations (SHAP) value for calculating a correlation degree of a value of each feature to a model output.

### ((Step S5))

In step S5, the feature extraction unit 34a extracts a feature having a large correlation degree calculated in step S4. As the extraction method, for example, a method for extracting N high-order features in descending order of the correlation degree or a method for extracting a feature having a correlation degree equal to or larger than a preset threshold can be used.

### ((Step S6))

In step S6, the feature-based calculation unit 34b calculates, as an abnormality degree of the operation process, a deviation degree in data between an evaluation point to which an error label of the feature, which is extracted in step S5 and has a large correlation with an error, is assigned and an evaluation point to which the error label is not assigned. As the deviation degree, for example, a Euclidean distance or a Mahalanobis distance can be used.

### ((Step S7))

In step S7, the abnormality degree storage unit 35 stores the abnormality degree for each operation process calculated in step S6.

### ((Step S8))

In step S8, it is determined whether the processing from step S3 to step S7 has been performed for all the operation process data extracted in step S1. When a requirement is satisfied, the processing proceeds to step S9, and when the requirement is not satisfied, the processing from step S3 to step S7 is repeated until the calculation of the abnormality degree for all the operation process data is completed.

### ((Step S9))

In step S9, the abnormal process estimation unit 36 estimates an operation process as the error cause by using the abnormality degree for each operation process stored in step S7. As an estimation method of the error cause process here, for example, an operation process having the highest abnormality degree, a most upstream operation process in which the abnormality degree is equal to or larger than a preset threshold, and an operation process estimated using a machine learning model that has trained a relationship among a feature highly correlated with an error correlation, an abnormality degree for each process, and a cause process can be used.

An estimation result of the error cause process in this step is output as the abnormal process estimation result D1. The abnormal process estimation result D1 is an error analysis result including the abnormality degree for each operation process stored in the abnormality degree storage unit 35, the error cause process estimated by the abnormal process estimation unit 36, or the like. These error analysis results are presented to the user via the terminal 4, which is a GUI.

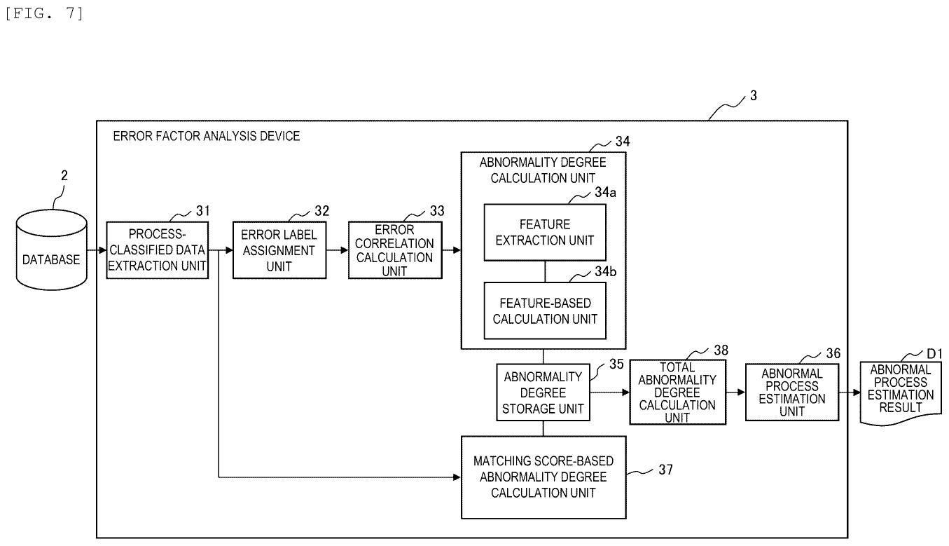

FIG. 6 illustrates an example of a method for presenting the error analysis result to the user. In this example, a magnitude of the abnormality degree for each operation process is indicated by a length of a bar, and the process P2 estimated to be the error cause by the processing of the flowchart of FIG. 4 is indicated by a color (dark color) different from the other processes. Accordingly, even if an error is detected in the process P5, it is possible to notify the user that a cause of the error has occurred in the process P2 in which no error is detected.

### (Effects of Embodiment 1)

In the embodiment described above, unlike an abnormality detection method in the related art in which a table or a definition needs to be prepared for each recipe, an error-related evaluation point included in the data of each preceding operation process is estimated using the generated error information as it is. Then, the error-related evaluation point is regarded as error data, and a deviation degree between the error data and other data is calculated as the abnormality degree for each process.

Accordingly, it is possible to estimate an error cause process without using a relationship table between a measurement value and the error cause process prepared in advance or collection and definition of normal data. Therefore, according to the embodiment, even when the recipe is frequently updated in order to manufacture small-lot and large variety semiconductor products, the error cause estimation corresponding to each recipe can be easily performed.

### Embodiment 2

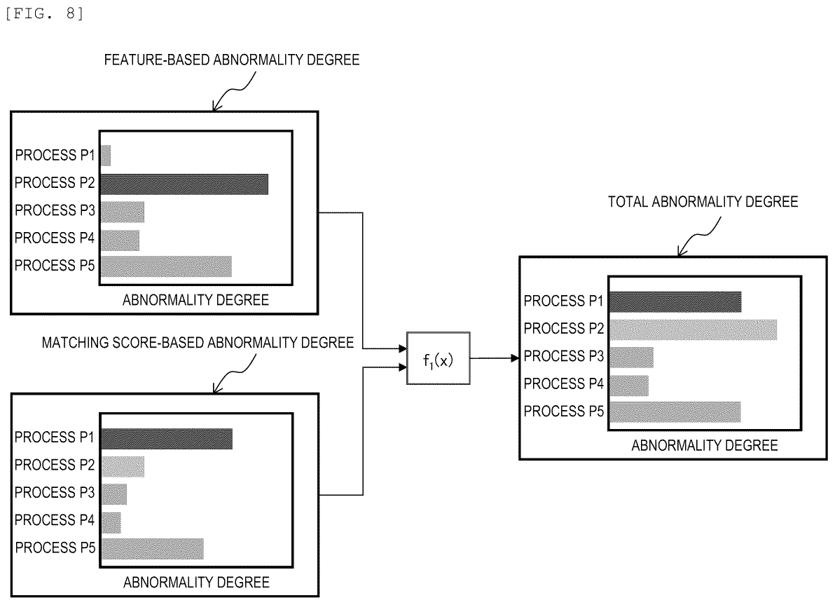

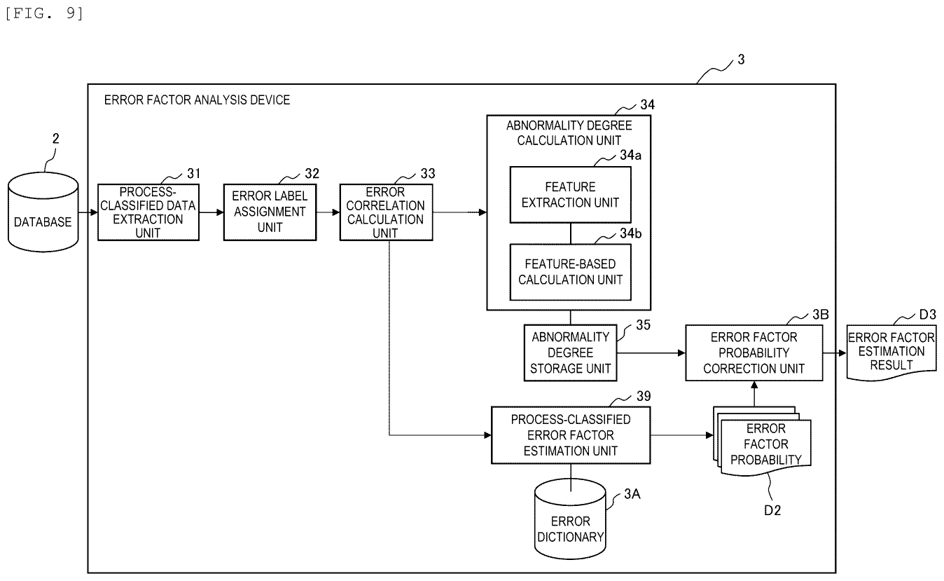

Next, the error factor analysis device 3 according to Embodiment 2 will be described with reference to FIGS. 7 and 8. A repeated description of points in common with Embodiment 1 will be omitted.

As is obvious from the comparison between FIGS. 3 and 7, the error factor analysis device 3 according to Embodiment 2 is obtained by adding a matching score-based abnormality degree calculation unit 37 and a total abnormality degree calculation unit 38 to the error factor analysis device 3 according to Embodiment 1. Hereinafter, these details will be sequentially described.

### (Matching Score-Based Abnormality Degree Calculation Unit 37)

In the database 2, generally, a matching score between a template image registered in advance in a recipe and an SEM image obtained by imaging an evaluation point is recorded. The matching score-based abnormality degree calculation unit 37 calculates, as an abnormality degree, a deviation degree in data between an evaluation point to which an error label of the matching score is assigned and an evaluation point to which the error label is not assigned, for data of each process that may be an error cause extracted by the process-classified data extraction unit 31. As the deviation degree, a Z score based on an average value or a standard deviation of original data can be used. The matching score-based abnormality degree for each process is stored in the abnormality degree storage unit 35.

### (Total Abnormality Degree Calculation Unit 38)

The total abnormality degree calculation unit 38 calculates a total abnormality degree based on each abnormality degree stored in the abnormality degree storage unit 35. FIG. 8 illustrates a schematic diagram of the total abnormality degree calculation. The total abnormality degree for each process is calculated based on a feature-based abnormality degree and a matching score-based abnormality degree. As the calculation method, for example, a method for simply adding both the abnormality degrees for each process, a method for taking a maximum value of both, a method for multiplying each by a preset weight and adding them, or the like can be used.

### (Abnormal Process Estimation Unit 36)

The abnormal process estimation unit 36 estimates a process as an error cause based on a height and a threshold of the abnormality degree as in Embodiment 1 by using the total abnormality degree for each process calculated by the total abnormality degree calculation unit 38.

When the total abnormality degree is calculated as in the embodiment, only a final total abnormality degree may be displayed on the terminal 4 which is a GUI, or both the feature-based abnormality degree and the matching score-based abnormality degree which are grounds for calculating the total abnormality degree may be displayed together with the total abnormality degree. In FIG. 8, similarly to FIG. 6, the process estimated as the error cause by the abnormal process estimation unit 36 is also indicated by a color (dark color) different from other processes, but when an estimation method of an error process adopted by the abnormal process estimation unit 36 is, for example, a method for estimating the most upstream process in which a magnitude of the abnormality degree exceeds a threshold as the process of the error cause, as in the example of FIG. 8, the most upstream process P1 in which the abnormality degree exceeds the threshold may be estimated as the error cause instead of the process P2 in which the abnormality degree is maximum.

### (Effects of Embodiment 2)

In Embodiment 2, a plurality of methods for calculating the abnormality degree for each process are provided, and an abnormality degree is calculated by combining them. Accordingly, it is possible to use multidirectional information for estimating an error cause process, and it is possible to improve estimation accuracy by reducing overlooking of a feature of an error.

### Embodiment 3

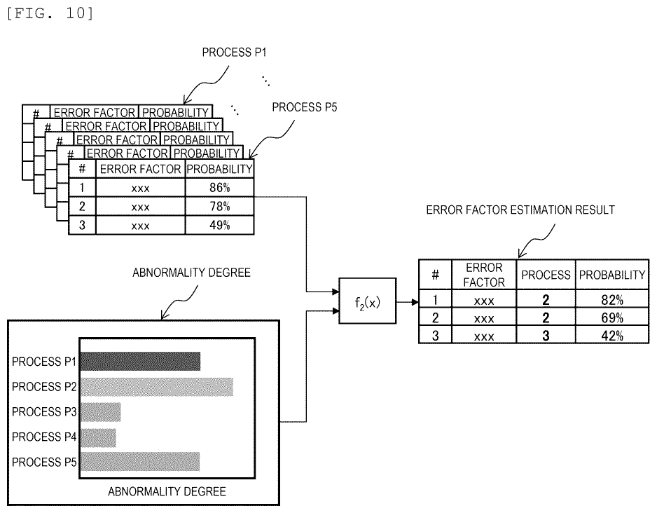

Next, the error factor analysis device 3 according to Embodiment 3 will be described with reference to FIGS. 9 and 10. A repeated description of points in common with Embodiment 1 will be omitted.

As can be seen from the comparison between FIGS. 3 and 9, unlike Embodiment 1, the error factor analysis device 3 according to Embodiment 3 includes a process-classified error factor estimation unit 39, an error dictionary 3A, and an error factor probability correction unit 3B. Hereinafter, these details will be sequentially described.

### (Process-Classified Error Factor Estimation Unit 39)

The process-classified error factor estimation unit 39 searches the error dictionary 3A for an item having a high similarity by using a feature having a high correlation degree with the error calculated by the error correlation calculation unit 33, a value of the feature, the correlation degree, or the like, and acquires, as an error factor probability D2, one or more searched error factors and a similarity thereof for each process. As a calculation method for the similarity, for example, estimation by collaborative filtering or rank learning can be used.

### (Error Information Storage Unit 3a)

The error dictionary 3A stores a combination of a feature, a value thereof, and a correlation degree, and an error factor thereof in association with each other. As the storage method, the feature of the error and the factor thereof may be systematized in a table format or the like based on past know-how, or past error data and an error factor thereof may be stored.

### (Error Factor Probability Correction Unit 3B)

The error factor probability correction unit 3B corrects the error factor probability D2 for each process calculated by the process-classified error factor estimation unit 39 by using the abnormality degree for each process stored in the abnormality degree storage unit 35. A schematic diagram of this correction method is illustrated in FIG. 10.

In FIG. 10, the error factors and the error probabilities calculated by the process-classified error factor estimation unit 39 are acquired for three high-order processes. The error probability is corrected by the abnormality degree for each process stored in the abnormality degree storage unit 35, and the high-order error probability after correction and a process number are acquired as an error factor estimation result D3. As the correction method, for example, the error probability may be multiplied by the value of the abnormality degree obtained by normalizing with [0.0 to 1.0], or the error probability may be multiplied by a coefficient calculated such that the process having an abnormality degree equal to or higher than a threshold becomes high and the process having an abnormality degree equal to or higher than the threshold becomes low. The error factor estimation result D3 thus obtained is presented to the user via the terminal 4.

### (Effects of Embodiment 3)

In Embodiment 3, by correcting an estimation probability of an error factor obtained for each process using an abnormality degree for each process, the error factor corresponding to the abnormality degree for each process can be estimated. Accordingly, even in a case where an error occurs due to an interaction among a plurality of processes, it is possible to extract an error factor in each process and present the error factor to the user.

### (Modification)

The disclosure is not limited to the embodiments described above, and includes various modifications. For example, the embodiments described above are described in detail to facilitate understanding of the disclosure, and it is not necessary to include all of the configurations described. A part of one embodiment can be replaced with a configuration of another embodiment. A configuration of another embodiment can be added to a configuration of one embodiment. A part of a configuration of each embodiment can be added, deleted, or replaced with a part of a configuration of another embodiment.

For example, in Embodiments 1 to 3 described above, an example in which the error factor of the semiconductor inspection device 1 is estimated has been described, but it is also possible to estimate an error factor of an error that occurs in a device other than the semiconductor inspection device 1.

In addition, in Embodiment 2 described above, the two abnormality degrees of the feature-based abnormality degree and the matching score-based abnormality degree are used as a calculation method for the abnormality degree for each process, and a calculation method for three or more abnormality degrees other than the two abnormality degrees may be used.

In Embodiment 3 described above, the process-classified error factor estimation unit 39, the error dictionary 3A, and the error factor probability correction unit 3B are added to the configuration of Embodiment 1, and may be added to the configuration of Embodiment 2.

In Embodiment 3 described above, the information stored in the error dictionary 3A may include a recipe correction plan, and the error factor and the recipe correction plan may be presented together as the information presented to the user by the error factor estimation result D3.

### REFERENCE SIGNS LIST

100: information processing system
1: semiconductor inspection device
2: database
3: error factor analysis device
31: process-classified data extraction unit
32: error label assignment unit
33: error correlation calculation unit
33a: feature generation unit
33b: error classification model training unit
33c: model analysis unit
34: abnormality degree calculation unit
34a: feature extraction unit
34b: abnormality degree calculation unit
35: abnormality degree storage unit
36: abnormal process estimation unit
37: matching score-based abnormality degree calculation unit
38: total abnormality degree calculation unit
39: process-classified error factor estimation unit
3A: error dictionary
3B: error factor probability correction unit
4: terminal
D1: abnormal process estimation result
D2: error factor probability
D3: error factor estimation result
N: network

1. An error factor analysis device that estimates, when a data set measured by an inspection device includes an error, a small process of an error cause from a plurality of small processes constituting an inspection process based on the data set, the error factor analysis device comprising:
an error label assignment unit configured to estimate an error-related evaluation point related to an evaluation point where an error is detected from evaluation points of small processes other than a small process including an evaluation point where an error is detected, and assign an error label to the evaluation point where the error is detected and the error-related evaluation point;
an error correlation calculation unit configured to estimate, based on a difference in data between an evaluation point to which the error label is assigned and an evaluation point to which the error label is not assigned, a feature having a large correlation with error occurrence for each small process;
an abnormality degree calculation unit configured to calculate a feature-based abnormality degree for each small process according to a degree of statistical data deviation between the evaluation point to which the error label is assigned and the evaluation point to which the error label is not assigned for the feature having the large correlation; and
an abnormal process estimation unit configured to estimate a small process of an error cause based on an abnormality degree for each small process.

2. The error factor analysis device according to claim 1, further comprising:
a second abnormality degree calculation unit configured to estimate a matching score between a template image of an evaluation point and a captured image of the evaluation point and calculate matching score-based abnormality degree according to a degree of statistical deviation of a matching score between the evaluation point to which the error label is assigned and the evaluation point to which the error label is not assigned; and
a total abnormality degree calculation unit configured to calculate a total abnormality degree for each small process based on the abnormality degree for each small process calculated by the abnormality degree calculation unit and the abnormality degree for each small process calculated by the second abnormality degree calculation unit, wherein
the abnormal process estimation unit estimates a small process of an error cause based on the total abnormality degree for each small process.

3. The error factor analysis device according to claim 1, further comprising:
an error dictionary in which a relationship between a feature of an error and an error factor or a parameter correction plan thereof is stored; and
a process-classified error factor estimation unit configured to search the error dictionary for an item similar to a combination of the feature having the large correlation and an error feature of statistical information of a measurement result, and extract a candidate of the error factor or the parameter correction plan for each small process.

4. The error factor analysis device according to claim 3, wherein
a similarity of the error factor or the parameter correction plan for each small process is corrected according to the abnormality degree for each small process, and a high-order error factor or parameter correction plan having a high similarity after correction is extracted from the error factors or the parameter correction plans for the small processes and is presented to a user.

5. The error factor analysis device according to claim 4, wherein
when a probability of an evaluation point where an error is detected is equal to or less than a threshold with respect to the number of evaluation points where no error occurs, a similarity of certain items among the extracted similarities after correction is lowered.

6. The error factor analysis device according to claim 1, wherein
the abnormal process estimation unit estimates a process in which the abnormality degree of each small process is equal to or larger than a threshold and which is a most upstream process as the small process of the error cause.

7. The error factor analysis device according to claim 2, wherein
the abnormal process estimation unit estimates a process in which the total abnormality degree for each small process is equal to or larger than a threshold and which is a most upstream process as the small process of the error cause.

8. The error factor analysis device according to claim 1, wherein
the abnormal process estimation unit constructs a model in which a relationship among the abnormality degree for each small process, an item of the feature having the large correlation or a correlation degree thereof, and an error cause process is trained, and sets a process estimated by the model as the error cause process.

9. The error factor analysis device according to claim 2, wherein
the abnormal process estimation unit constructs a model in which a relationship among the total abnormality degree for each small process, an item of the feature having the large correlation or a correlation degree thereof, and an error cause process is trained, and sets a process estimated by the model as the error cause process.

10. An error factor analysis method for estimating, when a data set measured by an inspection device includes an error, a small process of an error cause from a plurality of small processes constituting an inspection process based on the data set, the error factor analysis method comprising:
an error label assignment step of estimating an error-related evaluation point related to an evaluation point where an error is detected from evaluation points of small processes other than a small process including an evaluation point where an error is detected, and assigning an error label to the evaluation point where the error is detected and the error-related evaluation point;
an error correlation calculation step of estimating, based on a difference in data between an evaluation point to which the error label is assigned and an evaluation point to which the error label is not assigned, a feature having a large correlation with error occurrence for each small process;
an abnormality degree calculation step of calculating a feature-based abnormality degree for each small process according to a degree of statistical data deviation between the evaluation point to which the error label is assigned and the evaluation point to which the error label is not assigned for the feature having the large correlation; and
an abnormal process estimation step of estimating a small process of an error cause based on an abnormality degree for each small process.
